(19) United States
(12) Patent Application Publication
(10) Pub. No.: US 2023/0311249 A1
(43) Pub. Date: Oct. 5, 2023

(54) METAL PASTE FOR BONDING AND BONDING METHOD

(71) Applicant: DOWA ELECTRONICS MATERIALS CO., LTD., Tokyo (JP)

(72) Inventors: Keiichi ENDOH, Tokyo (JP); Toshihiko UEYAMA, Tokyo (JP)

(73) Assignee: DOWA ELECTRONICS MATERIALS CO., LTD., Tokyo (JP)

(21) Appl. No.: 18/024,840

(22) PCT Filed: Sep. 30, 2020
(86) PCT No.: PCT/JP2020/037105

§ 371 Date: Mar. 6, 2023

(51) Int. Cl. B23K 35/30; B23K 35/02

(52) U.S. Cl. CPC B23K 35/3006; B23K 35/025; B23K 2103/56

(57) ABSTRACT

There is provided a bonding paste capable of forming a uniform bonding layer by reducing occurrence of voids at edges even when a bonding area is large, and bonding method using the paste, and provides a metal paste for bonding containing at least metal nanoparticles (A) having a number average primary particle size of 10 to 100 nm, wherein a cumulative weight loss value (L₁₀₀) when a temperature is raised from 40° C. to 100° C. is 75 or less, and a cumulative weight loss value (L₁₅₀) when a temperature is raised from 40° C. to 150° C. is 90 or more, and a cumulative weight loss value (L₂₀₀) when a temperature is raised from 40° C. to 200° C. is 98 or more, based on 100 cumulative weight loss value (L₇₀₀) when the paste is heated from 40° C. to 700° C. at a heating rate of 3° C./min in a nitrogen atmosphere.

### BACKGROUND

### Technical Field

The present invention relates to a bonding material capable of forming a metal bonding layer with reduced voids at an edge between the layer and a member to be bonded, and a bonding method using the bonding material.

Conventionally, in a semiconductor device in which electronic parts such as a semiconductor chip are mounted on a substrate such as a copper substrate, the electronic parts were fixed on the substrate by soldering. However, in recent years, conventional solder containing lead is being replaced by lead-free solder, in consideration of a load on a human body and an environment.

Further, in such a semiconductor device, electronic parts are miniaturized to increase a mounting density on a substrate, and therefore, current density driving them tends to increase. As a result, heat generated during operation of the electronic parts also increases. Further, as a semiconductor element, the use of SiC elements, which have lower loss and superior characteristics than widely used Si elements, is being studied. In a semiconductor device having these SiC elements mounted on a substrate, an operating temperature may exceed 200° C. In the manufacture of the semiconductor device that exposed to such a high-temperature environment, high-temperature solder with a high melting point must be used as a solder for fixing electronic parts onto the substrate, but it is difficult to make such a lead-free high-temperature solder.

In the midst of these trends, the present applicant has so far disclosed such that by including nano-silver particles in a paste and appropriately controlling its composition, it is possible to provide a bonding method that exhibits high bonding strength and is excellent in high temperature durability even in a case of a low temperature treatment, and even without using lead which is an environmentally hazardous substance. (Patent Documents 1 and 2)

### PRIOR ART DOCUMENT

### Patent Document

[Patent Document 1] JP-A-2015-004105
[Patent Document 2] JP-A-2015-225842

### SUMMARY OF THE INVENTION

### Problem to be Solved by the Invention

As a technique disclosed in Patent Documents 1 and 2, there is provided a technique such that by using nano-sized silver particles and micron-sized silver particles in combination with a sintering aid and a phosphate ester additive, voids in the metal layer can be reduced, which are formed when a paste is applied and sintered.

However, according to the inventors' recent studies, even with a paste that has such a configuration optimized, it has been found that, particularly when performing bonding over a large area, adhesion failure may occur at an edge. When water or other liquids enter the gaps caused by poor bonding at the edge, it is presumed that there is a risk of gradual oxidation occurring from that portion. Therefore, there is a strong demand for a paste structure that does not cause poor adhesion even when a bonding area is large.

Therefore, in order to solve the above-described problem, an object of the present invention is to provide a bonding paste capable of reducing an occurrence of voids at an edge and forming a uniform bonding layer even when a bonding area is large, and a bonding method using this paste.

### Means for Solving the Problem

In order to solve the above-described problem, as strenuous efforts by the present inventors, it is found as follows. Regarding a paste, the above-described problem can be solved under an appropriate condition of not only a component to be added but also a property exhibited by the paste formed as a result of addition. Thus, the present invention is completed.

That is, according to a invention of this specification, a first invention provides a metal paste for bonding containing metal nanoparticles (A) having a number average primary particle size of at least 10 to 100 nm, wherein a cumulative weight loss value (L₁₀₀) when a temperature is raised from 40° C. to 100° C. is 75 or less, and a cumulative weight loss value (L₁₅₀) when a temperature is raised from 40° C. to 150° C. is 90 or more, and a cumulative weight loss value (L₂₀₀) when a temperature is raised from 40° C. to 200° C. is 98 or more, based on 100 cumulative weight loss value (L₇₀₀) when the paste is heated from 40° C. to 700° C. at a heating rate of 3° C./min in a nitrogen atmosphere.

A second invention provides the metal paste for bonding according to the first invention, wherein a cumulative weight loss value (L₂₀₀) when a temperature is raised from 40° C. to 200° C. is 99.9 or less.

A third invention provides the metal paste for bonding according to the first or second invention, wherein a solvent whose boiling point or decomposition temperature is Tb−50 (° C.) or more and Tb+50 (° C.) or less, accounts for 5% by mass or more and 10% by mass or less when a sintering temperature is Tb (° C.), based on 100% by mass total amount of the metal paste for bonding containing metal particles containing metal nanoparticles (A), solvents, and additives such as a dispersant.

A fourth invention provides the metal paste for bonding according to any one of the first invention to the third invention, the metal paste containing 1.5% by mass or less of a component whose boiling point or decomposition temperature is higher than the sintering temperature Tb+50 (° C.) when the sintering temperature is Tb (° C.), based on 100% by mass total amount of the metal paste for bonding containing metal particles containing metal nanoparticles (A), solvents, and additives such as a dispersant.

A fifth invention provides a metal paste for bonding, which is a metal paste for bonding containing metal particles containing metal nanoparticles (A) having a number average primary particle size of at least 10 to 100 nm, wherein a shrinkage rate of the metal particles contained in the paste is 1. 5% or less, the shrinkage rate being measured by thermomechanical analysis performed while pressurizing the metal particles at 0.1 MPa in a nitrogen atmosphere and raising a temperature from 30° C. to 250° C. at a rate of 3° C./min.

A sixth invention provides the metal paste for bonding according to the fifth invention, wherein a shrinkage rate of the metal particles to be used is 0.5% or less, the shrinkage rate being measured in thermomechanical analysis performed while raising a temperature from 30° C. to 200° C.

A seventh invention provides the metal paste for bonding according to the fifth invention or the sixth invention, wherein a shrinkage rate of the metal particles to be used is 0.3% or less, the shrinkage rate being measured in thermomechanical analysis performed while raising a temperature from 30° C. to 175° C.

An eighth invention provides a metal paste for bonding according to any one of the first to seventh inventions, the metal paste further containing metal particles (B) whose average particle size (D₅₀) is 1.0 to 5.0 μm in terms of volume measured by a laser diffraction particle size distribution device.

A ninth invention provides the metal paste for bonding according to the eighth invention, wherein a weight mixing ratio of metal nanoparticles (A) to metal particles (B), (A)/(B), is 0.25 or less.

A tenth invention provides a bonding method which is a method for bonding two members to be bonded, the method including:
applying the metal paste for bonding according to any one of the inventions 1 to 9, to a member to be bonded;
placing one member to be bonded on which the paste is applied on a coating film, on the other member to be bonded; and
raising a temperature to a sintering temperature of 200 to 350° C. after placing the members, and maintaining the sintering temperature for less than 2 hours to form a metal bonding layer.

An eleventh invention provides the bonding method according to the tenth invention, including drying at a temperature of 50 to 150° C. after applying the metal paste for bonding.

A twelfth invention provides the bonding method according to the tenth invention or the eleventh invention, wherein a temperature rise rate from a room temperature to a sintering temperature is 1.5 to 10° C. per minute.

A thirteenth invention provides the bonding method according to any one of the tenth invention to the twelfth invention, wherein an area (bonding area) to which the metal paste for bonding is applied is 9 mm² or more.

### Advantage of the Invention

According to the present invention, an occurrence of voids at an edge can be reduced and a uniform bonding layer can be formed even when a bonding area is large, and a joined body having high bonding strength can be formed.

### BRIEF DESCRIPTION OF THE DRAWING

FIG. 1 is a schematic view illustrating manner of measuring a shear strength of a joined body.

FIG. 2 is a result of photographing a joint with a microfocus X-ray transmission apparatus, the joint being formed using a metal paste for bonding in example 3.

FIG. 3 is a result of photographing a joint with a microfocus X-ray transmission apparatus, the joint being formed using a metal paste for bonding in comparative example 4.

### DETAILED DESCRIPTION OF THE INVENTION

A metal paste for bonding and a bonding method according to the present invention will be described.

### <Metal Paste for Bonding>

A metal paste for bonding comprises specific metal particles, solvents, and additive components that complement properties.

### [Metal Nanoparticles]

Commercially available particles and particles described in documents can be employed as metal nanoparticles used in the present invention, in addition to what an applicant has already marketed, as long as it follows a spirit of the present invention. As for the method for producing nanoparticles, particles produced by either a wet method or a dry method can be employed as long as a particle size range and properties specified in the present invention are satisfied. An average primary particle size (number average particle size calculated from a transmission electron micrograph and a scanning electron micrograph) of metal nanoparticles according to the spirit of the present invention is 10 to 100 nm, preferably to 80 nm, more preferably 20 to 60 nm, even more preferably 20 to 40 nm. The number average particle size is also referred to as a number average value of a primary particle size. An organic coating (capping layer) is preferably formed on surfaces of the particles to suppress spontaneous sintering. As the particle size becomes smaller, a melting temperature of the metal nanoparticles becomes lower, which is preferable because a temperature for forming a joined body can be lowered. However, when the metal nanoparticles are too small, a thick capping layer must be formed to avoid sintering at a room temperature, which is not preferable. When a thick capping layer is formed, it is easy to disperse between particles, making it easier to obtain a monodispersed product, but in order to remove the capping layer and promote metal sintering, the thick capping layer is not preferable because it requires a high-temperature treatment, and organic substance remains in the metal layer, which may cause a decrease in bonding strength and a decrease in electrical conductivity. Further, when the particles are too monodispersed, it becomes difficult to recover the particles, which also causes a decrease in productivity.

In order to form a high bonding strength, it is preferable that the capping layer comprises a substance having low-temperature decomposability that can be removed at a temperature for forming the metal layer. When a substance with a large molecular weight is used, a sintering residue will remain in a sintered layer, which is not preferable. Therefore, polymers and macromolecular substances should be avoided. The organic substance that constitutes the capping layer is preferably a substance having a boiling point at least equal to or lower than the sintering temperature, preferably a substance having a boiling point of 300° C. or lower, preferably 250° C. or lower. Examples of such organic compounds include carboxylic acids having 12 or less carbon atoms, dicarboxylic acids, unsaturated fatty acids, amines, thiols, and sulfides, in which the carboxylic acids, dicarboxylic acids, unsaturated fatty acids and amines are particularly preferable. Specifically, octanoic acid, heptanoic acid, hexanoic acid, pentanoic acid, butanoic acid, propanoic acid, oxalic acid, malonic acid, ethylmalonic acid, succinic acid, methylsuccinic acid, glutaric acid, adipic acid, pimelic acid, suberic acid, sorbic acid, maleic acid, hexylamine, octylamine, etc., can be exemplified.

When an amount of organic substance coating the surface increases, the sintering temperature will rise and impurities may remain in a sintered film, which is inappropriate. The coating amount of the organic substance with respect to the metal nanoparticles (powder) is 0.1% by mass or more and 10% by mass or less, preferably 0.5% by mass or more and 5% by mass or less, more preferably 1.0% by mass or more and 3.0% by mass or less.

Further, it is preferable that the particles shrink less when heated. Specifically, it is preferable that a shrinkage rate is 1.5% or less, preferably 1.0% or less, and preferably 0.75% or less, the shrinkage rate being measured by thermomechanical analysis performed while raising the temperature from 30° C. to 250° C. at a rate of 3° C./min under a nitrogen atmosphere while pressurizing at 0.1 MPa. It is preferable that the shrinkage rate is 0.5% or less, the shrinkage rate being measured by thermomechanical analysis performed while raising the temperature from 30° C. to 200° C. at a rate of 3° C./min under a nitrogen atmosphere while pressurizing at 0.1 MPa. It is preferable that the shrinkage rate is 0.3% or less, the shrinkage rate being measured by thermomechanical analysis performed while raising the temperature from 30° C. to 175° C. at a rate of 3° C./min under a nitrogen atmosphere while pressurizing at 0.1 MPa.

The metal used for the metal nanoparticles is not particularly limited as long as it can be used for bonding members. Both noble and base metals can be used. Examples of the noble metals include silver, gold, ruthenium, rhodium, palladium, iridium, platinum, etc. Silver, gold, etc., can be preferably used in consideration of ease of acquisition. Silver is particularly preferable from a viewpoint of a cost. Examples of base metals include copper, aluminum, iron, nickel, etc. Here, the metal that can be used may be a single metal or an alloy.

### [Metal Particles]

In the present invention, when metal particles are used in combination, commercially available metal particles can be employed. The particles at this time may be those prepared by a wet method or those prepared by a dry method. The metal particles used in the present invention include metal particles whose volume-equivalent cumulative 50% particle size (D₅₀ particle size) is 1.0 to 5.0 μm measured with a laser diffraction particle size distribution device. When the metal paste (coating film) is sintered, the metal nanoparticles are sintered to connect the metal particles to form a metal bonding layer. At this time, in order to prevent a formation of voids in the metal bonding layer, the D₅₀ particle size of the metal particles is preferably 1.2 to 3.0 μm, more preferably 1.4 to 2.0 μm.

The metal particles may also be coated with an organic compound to improve dispersibility, etc. In this case, the metal particles are preferably coated with an organic compound having 20 or less carbon atoms. Examples of such organic compounds include oleic acid and stearic acid. It is preferable that an amount of the coating organic substance is as small as an amount of the metal nanoparticles, because an adverse effect on a metal layer can be suppressed. Specifically, the amount of the coating organic substance is 5.0% by mass or less, preferably 3.0% by mass or less.

Further, as described in the explanation of the metal nanoparticles, it is preferable that the particles shrink less when heated. However, when metal particles are used together, it is preferable that the metal nanoparticles and the metal particles have similar properties after being mixed. Specifically, as for a mixture of the metal nanoparticles and metal particles, the shrinkage rate is 1.5% or less, preferably 1.0% or less, more preferably 0.75% or less, the shrinkage rate being measured by thermomechanical analysis performed while raising the temperature from 30° C. to 250° C. at a rate of 3° C./min under a nitrogen atmosphere while pressurizing at 0.1 MPa. It is preferable that the shrinkage rate is 0.5% or less, the shrinkage rate being measured by thermomechanical analysis performed while raising the temperature from 30° C. to 200° C. at a rate of 3° C./min under a nitrogen atmosphere while pressurizing at 0.1 MPa. It is preferable that the shrinkage rate is 0.3% or less, the shrinkage rate being measured by thermomechanical analysis performed while raising the temperature from 30° C. to 175° C. at a rate of 3° C./min under a nitrogen atmosphere while pressurizing at 0.1 MPa.

The metal used for the metal particles is not particularly limited as long as it can be used for bonding members. Both noble and base metals can be used. Examples of the noble metals include silver, gold, ruthenium, rhodium, palladium, iridium, platinum, etc. Silver, gold, etc., can be preferably used in consideration of ease of acquisition. Silver is particularly preferable from a viewpoint of a cost. Examples of the base metals include copper, aluminum, iron, nickel, etc. Here, the metal that can be used may be a single metal or an alloy. Here, the same metal as the metal nanoparticles may be used, or a different metal may be used.

When the metal particles are added in addition to the metal nanoparticles, a weight mixing ratio of the metal nanoparticles (A) and the metal particles (B), (A)/(B), is preferably 0.25 or less. Further, a proportion of the metal nanoparticles or a mixture of the metal nanoparticles and the metal particles in the metal paste for bonding is preferably 90% by mass or more.

### [Solvents]

The solvents used in the present invention should preferably have a property of volatilizing at a temperature lower than the sintering temperature. Volatilization may be evaporation by boiling or decomposition. Specifically, it is preferable to employ the solvent whose boiling point or a decomposition temperature is 300° C. or lower.

The solvent used in the present invention may be either a polar solvent or a non-polar solvent, provided that it does not affect sintering, etc. However, it is more appropriate to select a polar solvent, in consideration of compatibility with other component.

As the solvent used here, a plurality of solvents can be mixed and used for the purpose of adjusting the boiling point, viscosity and evaporation rate of the metal paste. The following solvents are examples of the polar solvents which can be mixed.

Water; monoalcohols such as terpineol, texanol, phenoxypropanol, 1-octanol, 1-decanol, 1-dodecanol, 1-tetradecanol, Terusolve MTPH (manufactured by Nippon Terpene Chemicals, Inc.), dihydroterpinyloxyethanol (manufactured by Nippon Terpene Chemicals, Inc.), Terusolve TOE-100 (manufactured by Nippon Terpene Chemicals, Inc.), Terusolve DTO-210 (manufactured by Nippon Terpene Chemicals, Inc.); polyols such as 3-methyl-1,3-butanediol, 2-ethyl-1,3-hexanediol (octanediol), hexyl diglycol, 2-ethylhexyl glycol, dibutyl diglycol, glycerin, dihydroxyterpineol, 3-methylbutane-1,2,3-triol (Isoprene triol A (IPTL-A), manufactured by Nippon Terpene Chemicals, Inc.), 2-methylbutane-1,3,4-triol (Isoprene triol B (IPTL-B), manufactured by Nippon Terpene Chemicals, Inc.); ether compounds such as butyl carbitol, diethylene glycol monobutyl ether, terpinyl methyl ether (manufactured by Nippon Terpene Chemicals, Inc.), dihydroterpinyl methyl ether (manufactured by Nippon Terpene Chemicals, Inc.); glycol ether acetate such as butyl carbitol acetate, diethylene glycol monobutyl ether acetate, ethylene glycol monomethyl ether acetate, ethylene glycol monoethyl ether acetate, diethylene glycol monoethyl ether acetate; nitrogen-containing cyclic compounds such as 1-methylpyrrolidinone, pyridine; ester compounds such as γ-butyrolactone, methoxybutyl acetate, methoxypropyl acetate, ethyl lactate, 3-hydroxy-3-methylbutyl acetate, dihydroterpinyl acetate, Terusolve IPG-2Ac (manufactured by Nippon Terpene Chemicals, Inc.), Terusolve THA-90 (manufactured by Nippon Terpene Chemicals, Inc.), Terusolve THA-70 (manufactured by Nippon Terpene Chemicals, Inc.).

It is found by the present inventors that when selecting such a solvent mixture, by appropriately adjusting a boiling point (or decomposition temperature), the rate at which the metal layer is formed can be adjusted, and the metal layer can be properly configured. Specifically, by mixing multiple solvents with different boiling points, the cumulative value of a weight loss estimated in each stage of sintering measured in a nitrogen atmosphere is set to a specific range. Thereby, solvents and additives generated during sintering, and gas components generated during volatilization and decomposition of organic substances that constitute the surface of metal particles can be avoided from remaining more than necessary.

### [Solvent Structure Classified According to Each Boiling Point]

According to the present invention, an important thing is as follows: as for the solvent candidates described above, by classifying their boiling points into hierarchies and combining them, the timing of boiling and decomposition of the solvent is not performed at once, but is performed in several steps in the stage of forming the metal layer. Thereby, it is possible to alleviate an excessive shrinkage of the metal layer due to sintering.

According to the inventor's study, the finding is that broadly speaking, it is appropriate that a composition of the paste according to the present invention has a configuration that includes both a solvent (S_{A}) whose boiling point or decomposition temperature (a temperature to be sintered: Tb) is ±50° C., and a solvent whose boiling point or decomposition temperature (a temperature to be sintered: Tb) is +50° C. or higher or a persistent organic substance (in Table 1 below, they are collectively included in the category of solvents and collectively referred to as a component S_{B}), with (a temperature to be sintered: Tb) as a median value, and it is appropriate that a proportion of the solvent (S_{A}) in an entire paste is 5% by mass or more and 10% by mass or less, the solvent (S_{A}) being the solvent whose boiling point or decomposition temperature (a temperature to be sintered: Tb) is ±50° C., with (a temperature to be sintered) as a median value, and a proportion of the component (S_{B}) in an entire paste is more than 0% by mass and 1.5% by mass % or less, the component (S_{B}) being the component whose boiling point or decomposition temperature is higher than (a temperature to be sintered: Tb)+50° C. As a specific example, when the sintering temperature (Tb) is set to 250° C. (see examples and comparative examples described later), S_{A} range is 200 to 300° C., and it means that the composition of the paste is determined by a component whose boiling point or decomposition temperature is 200° C. or higher and 300° C. or lower and a component whose boiling point or decomposition temperature is higher than 300° C. That is, in the present invention, the presence of an organic substance or organic-derived carbon having a high boiling point is allowed in the metal layer. It is presumed that the presence of this high boiling point organic substance has a function of suppressing excessive sintering of the metal component after a surface coating is detached during sintering. However, too much of such material is not suitable as it interferes with the sintering of the particles and adversely affects a bonding strength.

As a specific example, blending of the solvents when the sintering temperature is set to 250° C. will be described. When the sintering temperature (Tb) is set to 250° C., a boundary temperature of the boiling point or the decomposition temperature is 300° C., and as for the composition of the solvent, a solvent having a boiling point or a decomposition temperature of 200 to 300° C. and a solvent having a temperature higher than 300° C. are mixed. At this time, examples of the solvent (S_{A}) having a boiling point or decomposition temperature of 200 to 300° C. include 1-decanol (boiling point (nominal value): 233° C.), 3-methylbutane-1,2,3-triol (Isoprene triol A (IPTL-A)) (boiling point (nominal value): 255° C., manufactured by Nippon Terpene Chemicals, Inc.), 2-methylbutane-1,3,4-triol (Isoprene triol B (IPTL-B)) (boiling point ((nominal value): 278° C., manufactured by Nippon Terpene Chemicals, Inc.) and diethylene glycol (boiling point ((nominal value): 245° C.). Here, it is presumed that the solvent whose boiling point or decomposition temperature (temperature to be sintered: Tb) is ±50° C., with (a temperature to be sintered: Tb) as a median value, has a function of quickly removing the organic substance that protects the surface, from the particle surface particularly in an initial stage of forming the bonding layer. Since these solvents have a low boiling point or decomposition point, they must be blended in a large amount, especially in the case of the solvents that constitute the paste, and it is appropriate that the solvent accounts for at least 5% by mass or more and 10% by mass or less of a total mass. These solvents also have a low viscosity, so when adding them too much, they become ink-like, and it is not suitable because it becomes difficult to apply to a desired shape. According to the finding by the present inventors, in order to obtain appropriate fine voids after coating and sintering, the boiling point or decomposition temperature is preferably in a range of Tb−50 (° C.) to Tb+50 (° C.) when the sintering temperature is Tb (° C.). Specifically, for example, when the sintering temperature is 250° C., the bonding strength and fine voids can appear in a well-balanced manner by addition of the solvents whose boiling point or decomposition temperature is between 250° C. and 300° C., which is preferable. When the sintering temperature is Tb (° C.), it is preferable that the solvent whose boiling point or decomposition temperature is Tb−50 (° C.) or higher and Tb+50 (° C.) or lower preferably accounts for 5% by mass or more and 10% by mass or less, based on 100% by mass of the total amount of the metal paste for bonding containing metal particles containing metal nanoparticles, solvents, and additives such as a dispersant. A component having a boiling point or a decomposition temperature higher than the sintering temperature Tb+50 (° C.) is preferably contained in an amount of more than 0% by mass and 1.5% by mass or less. The sintering temperature Tb may be set to a value within a range of 200 to 300° C.

Examples of the solvent (S_{B}) having a boiling point or decomposition temperature higher than 300° C. (Tb+50° C.) when the sintering temperature (Tb) is set to 250° C. include: Tersolve MTPH (boiling point (nominal value): 308 to 318° C., manufactured by Nippon Terpene Chemical Co., Ltd.) and SOLPLUS 540 (boiling point: 700° C.). As for the boiling point or the decomposition temperature described here, it is possible to use a numerical value described in the manufacturer's SDS or the like, or a value calculated by oneself by TG/DTA or the like. At that time, a measurement start temperature is 25° C., the temperature is raised from 25° C. at a rate of 3° C./min, and a temperature when a heat loss reaches 95% is taken as a boiling point of the substance. When the heat loss is less than 95% even when the temperature is raised to 700° C., the boiling point of the substance is assumed to be 700° C. for convenience.

Too much of such material is not suitable as it interferes with the sintering of the particles and adversely affects the bonding strength. When the solvent having a boiling point or decomposition temperature exceeding 300° C. (sintering temperature of 250° C.+50° C.) is added more than necessary, it interferes with sintering, and care must be taken because an unsintered portion may occur. According to the fining by the present inventors, greater than 0% by mass and 2.5% by mass or less, preferably 1.5% by mass or less, more preferably 1.0% by mass or less, and even more preferably 0.5% by mass or less of such a solvent is preferable. A composition ratio of an amount of the solvent whose sintering temperature is higher than 300° C. (sintering temperature 250° C.+50° C.) with respect to an amount of the solvent whose sintering temperature is 300° C. or lower (sintering temperature 250° C.+50° C.) is as follows: the composition ratio of the solvent whose sintering temperature is higher than 300° C. (sintering temperature 250° C.+50° C.) with respect to the solvent whose sintering temperature is 300° C. or lower (sintering temperature 250° C.+50° C.) is preferably such that the solvent whose sintering temperature is higher than 300° C. (sintering temperature 250° C.+50° C.) is 1 and the solvent whose sintering temperature is 300° C. or lower (sintering temperature 250° C.+50° C.) is 9 or more (the composition of the solvent whose sintering temperature is higher than (sintering temperature 250° C.+50° C.) is 10% or less in an entire solvent).

It is preferable that the content of the solvent whose boiling point or decomposition temperature is 230° C. or more and 300° C. or less in the bonding material accounts for 50% or more of the total mass of the solvent in the bonding material. It is preferable that the content of the solvent whose boiling point or decomposition temperature is higher than 300° C. in the bonding material accounts for 35% or less of the total mass of the solvent in the bonding material. A lower limit is preferably 2%, more preferably 3%. It is preferable that the content of the solvent whose boiling point or decomposition temperature is 400° C. or higher in the bonding material accounts for 6% or less of the total mass of the solvent in the bonding material. A lower limit is preferably 3%. It is preferable to satisfy any one of the above content specifications, and more preferable to satisfy all of the content specifications.

### [Cumulative Value L₇₀₀ of a Weight Loss at 700° C.]

A weight loss of the metal paste at 40 to 700° C. is the sum of the solvents, additives, and organic substances that constitute the surfaces of the particles. The amount of weight loss after heat treatment at a temperature much higher than the heat treatment temperature (up to 300° C.) in the paste of the present invention is used as a standard because the purpose is to calculate an amount that can be removed as an organic substance in the paste based on a temperature at which even a flame-retardant or persistent substance in the paste can be removed. When the temperature is higher than this temperature, sintering of metal proceeds and the organic substance remains trapped in the metal layer and becomes useless, which is not suitable. Hereinafter, the amount of weight loss is also referred to as a weight loss value.

Methods for calculating the weight loss include: for example, a method of preparing a paste, heating it sufficiently at 40° C., measuring a weight, setting a temperature in a chamber to 700° C., and placing it in an electric furnace purged with nitrogen and sufficiently heated, then, taking it out from the furnace, and measuring its weight again to calculate from a weight loss before and after the heat treatment at 700° C., and a method of calculating the weight loss using a commercially available TG/DTA device. The latter method is suitable because not only can a desired heating rate be obtained, but also an amount of decrease at 100° C. and an amount of decrease at 150° C. can be calculated at once. An example of the method of measuring the weight loss using the TG/DTA device includes a method of weighing 10±1 mmg of a bonding material into an alumina pan for measurement (φ0.5 mm) using TG/DTA (TG/DTA6300) manufactured by SII, and calculating by raising a temperature from 40° C. to 700° C. at a heating rate of 3° C./min under a nitrogen atmosphere of 200 mL/min.

### [Cumulative Value L₁₀₀ of the Weight Loss at 100° C.]

The weight loss of the metal paste in the present invention at 40 to 100° C. in nitrogen is 25 or more and 75 or less, preferably 30 or more and 70 or less, more preferably 60 or less, and even more preferably 50 or less, based on 100 weight loss cumulative value L₇₀₀ at 40 to 700° C. When this value is greater than 70, it indicates that the solvent is desorbed from the paste at once in a low temperature range, which may cause non-uniform sintering, which is not preferable. Further, since a certain amount of such a non-metal component as a solvent remains, the decrease in the number of contacts between the metal nanoparticles and the member to be bonded is suppressed, due to opposite directions of a thermal expansion of a member to be bonded caused by temperature rise and a shrinkage of a coating film formed by the bonding material, which contributes to favorable formation of a metal layer, which is preferable.

### [Cumulative Value L₁₅₀ of the Weight Loss at 150° C.]

The weight loss of the metal paste in the present invention at 40 to 150° C. in nitrogen is 90 or more, preferably 93 or more, more preferably 95 or more, based on 100 weight loss cumulative value L₇₀₀ at 40 to 700° C. When this value is low, the paste contains a large amount of difficult-to-decompose and difficult-to-remove components, which may affect the formation of the metal layer, which is not preferable.

### [Cumulative Value L₂₀₀ of the Weight Loss at 200° C.]

The weight loss of the metal paste in the present invention at 40 to 200° C. in nitrogen is 95 or more, preferably 98 or more, based on 100 weight loss cumulative value L₇₀₀ at 40 to 700° C. When this value is low, the paste contains a large amount of difficult-to-decompose and difficult-to-remove components, which may affect the formation of the metal layer, which is not preferable. When this value exceeds 99.9, sintering of the particles may proceed locally when the sintering temperature is set to 200 to 300° C., which is not preferable.

### [Other Additives]

Known additives can be added to the paste of the present invention within an appropriate range as long as they do not affect the sinterability and the bonding strength of the paste. Specifically, dispersants such as acid dispersants and phosphate ester dispersants, sintering accelerators such as glass frit, antioxidants, viscosity modifiers, organic binders (e.g. resin binders), inorganic binders, pH adjusters, buffers, antifoaming agents, leveling agents, and volatilization inhibitors, can be added. The content of the additives in the bonding material is preferably 0.1% by mass or less.

### <Method for Producing Metal Paste>

The metal paste of the present invention can be produced by kneading metal nanoparticles, solvents, and other optional components by a known method. A kneading method is not particularly limited, and for example, the metal paste for bonding can be produced by preparing each component separately and kneading it in an arbitrary order by ultrasonic dispersion, disper, three-roll mill, ball mill, bead mill, twin-screw kneader, or revolution stirrer, etc.

### <Bonding Method>

The bonding according to the present invention means a method of bonding two members to be bonded using an embodiment of the bonding material of the present invention, and by this method, it is possible to form a uniform bonding layer up to an edge, and to obtain a joined body having a high bonding strength and a sufficiently reduced amount of voids in the metal bonding layer. The bonding method according to an embodiment of the present invention includes a coating film forming step, a placing step, and a sintering step, and may also includes a preliminary drying step, etc. Each of these steps will be described below.

### [Coating Film Forming Step]

In this step, the metal paste for bonding of the present invention is applied to one member to be bonded by a printing method such as screen printing, metal mask printing, or inkjet printing to form a coating film. Depending on the printing method selected, the viscosity of the paste or ink can be adjusted accordingly. An example of the one member to be bonded includes a substrate. Examples of the substrate include: a metal substrate such as a copper substrate, an alloy substrate of copper and some metal (for example, W (tungsten) or Mo (molybdenum)), a ceramic substrate in which a copper plate is sandwiched between SiN (silicon nitride) or MN (aluminum nitride), and in addition, a plastic substrate such as a PET (polyethylene terephthalate) substrate, and in some cases a printed wiring board, etc. Further, the bonding method of the present invention can also be applied to a laminated substrate in which these are laminated. A portion of the member to be bonded to which the bonding material is applied may be plated with a metal. From a viewpoint of bonding compatibility with a metal component in the coating film, the type of metal in the metal plating of the one member to be bonded may be the same as the constituent metal of the metal component in the bonding material.

### [Placing Step]

Subsequently, the other member to be bonded is placed on the coating film formed on the one member to be bonded. Examples of the other member to be bonded include a semiconductor element such as a Si chip and a SiC chip, and a substrate similar to the examples of the one member to be bonded. Further, it is also possible to prepare by applying paste to a back surface of the Si chip, SiC chip, or IC chip without applying the paste to the substrate.

Further, a portion of the other member to be bonded that is in contact with the coating film (surface to be bonded) may be plated with a metal. From a viewpoint of bonding compatibility with a metal component in the coating film, the type of the metal used in the metal plating of the other member to be bonded is preferably the same as the constituent metal of the metal component in the bonding material. When placing the member to be bonded on the coating film, it is not prohibited to apply pressure between two members to be bonded from the outside in a direction of compressing the coating film other than a weight of an object to be bonded, but it is important to set the pressure to such an extent that the chip, substrate, etc. are not destroyed by external pressure.

Further, the embodiment of the bonding method of the present invention can be suitably applied to bonding a large-area semiconductor element. Particularly, the embodiment of the bonding method of the present invention is suitable when the area of the surface to be bonded of the semiconductor element is 9 mm or more, (which is the surface in contact with the coating film or the metal bonding layer to be formed therefrom, the coating film being generally formed so as to cover an entire bottom surface of the semiconductor element), and is more preferable when the area of the surface to be bonded is 25 mm² or more, and is particularly preferable when the area of the surface to be bonded is 36 to 400 mm².

### [Preliminary Drying Step]

When heating and sintering the coating film on which the other member to be bonded is placed, a preliminary drying step for pre-drying the coating film may be performed before or after placing the other member to be bonded on the coating film (before or after the placing step), for the purpose of removing an excess organic component. The purpose of performing the preliminary drying is to remove a portion of the solvent from the coating film, and drying is performed under a condition of volatilizing the solvent and not substantially sintering the metal nanoparticles.

Therefore, the preliminary drying is preferably performed by heating the coating film at 60 to 150° C. This drying by heating may be performed under an atmospheric pressure, or may be performed under a reduced pressure or vacuum. Also, in the sintering step described below, when the heating rate up to the sintering temperature is 7° C./min or less, the preliminary drying step can be performed by raising the temperature up to the sintering temperature. When a metal that is easily oxidized is included as a component of the substrate or metal particles (for example, it is assumed that copper or a copper alloy is used as the substrate metal or metal particles), it is preferable to perform the preliminary drying step in an inert atmosphere from a viewpoint of preventing oxidation.

### [Sintering Step]

After performing the placing step and performing the preliminary drying step as necessary, the coating film sandwiched between the two members to be bonded is heated from a room temperature to a sintering temperature of 200 to 350° C. at a heating rate of 1.5° C./min to 10° C./min, and the sintering temperature is maintained for 1 minute or more and less than 2 hours to form a metal bonding layer from the coating film. This metal bonding layer has an excellent bonding strength and few voids. Accordingly, by this sintering, two members to be bonded can be firmly joined with high reliability.

The heating rate when heating to the sintering temperature in the sintering step is preferably 2° C./min to 6° C./min, more preferably 2.5° C./min to 4° C./min, from a viewpoint of forming a joined body having a metal bonding layer with a high bonding strength and few voids. Further, with such a rate of temperature rise, the temperature rise up to the sintering temperature can also serve as the preliminary drying step.

The sintering temperature is preferably 220 to 300° C. from a viewpoint of the bonding strength and the cost of the metal bonding layer to be formed. The holding time at the sintering temperature is preferably 1 to 90 minutes from a viewpoint of the bonding strength and the cost of the metal bonding layer to be formed. Further, during heating to the sintering temperature and holding at the sintering temperature, it is not necessary to apply pressure in a direction of compressing the coating film between the members to be bonded, but for the purpose of forming a denser sintered film, applying a pressure of 5 MPa or less is not prohibited.

Further, the sintering step may be performed in an air atmosphere or in an inert atmosphere such as a nitrogen atmosphere, but it is preferable to perform in the inert atmosphere from a viewpoint of preventing oxidation, and more preferably, the sintering step is performed in a nitrogen atmosphere from a viewpoint of a cost, particularly when the substrate or the metal particles contain a metal that is easily oxidized as a component (for example, when assuming that copper or a copper alloy is used as the metal of the substrate or the metal particles),

It is confirmed that the metal layer formed after sintering is a dense metal layer in which voids are not visible when viewed in a macroscopic region, but when viewed in an X-ray transmission image, the metal layer has voids with a very small diameter. Generally, voids should be as few as possible, but in the paste according to the present invention, a higher bonding strength can be obtained when voids having a small particle size are present to some extent. However, too many voids are undesirable as they can adversely affect a fatigue life in the joint. An occupancy ratio of the voids calculated from the X-ray transmission image is preferably 10% or less, preferably 5% or less, and more preferably 3% or less.

### EXAMPLES

The present invention will be described in more detail below using examples and comparative examples, but the present invention is not limited thereto.

### Preparation of Metal Paste for Bonding (Examples 1 to 5, Comparative Examples 1 to 7)

### [Preparation of Metal Nanoparticles]

3400 g of water was put in a 5 L reaction tank, and nitrogen was passed through the water in the reaction tank at a flow rate of 3000 mL/min from a nozzle provided at a bottom of the reaction tank for 600 seconds to remove dissolved oxygen, then, nitrogen was supplied into the reaction tank from a top of the reaction tank at a flow rate of 3000 mL/min to make an inside of the reaction tank a nitrogen atmosphere, and while stirring with a stirring rod equipped with a stirring blade provided in the reaction tank, a temperature of the water in the reaction tank was adjusted to 60° C. After adding 7 g of ammonia water containing 28% by mass of ammonia to the water in the reaction tank, a mixture was stirred for 1 minute to form a uniform solution. 45.5 g of saturated fatty acid hexanoic acid (manufactured by Wako Pure Chemical Industries, Ltd.) (molar ratio to silver: 1.98) was added as an organic compound to the solution in the reaction tank and a mixture was stirred for 4 minutes to dissolve the saturated fatty acid hexanoic acid, then, 23.9 g (4.82 equivalents with respect to silver) of 50% by mass hydrazine hydrate (manufactured by Otsuka Chemical Co., Ltd.) was added as a reducing agent to prepare a reducing agent solution.

Further, a silver nitrate aqueous solution prepared by dissolving 33.8 g of silver nitrate crystals (manufactured by Wako Pure Chemical Industries, Ltd.) in 180 g of water was prepared as a silver salt aqueous solution, and the temperature of the silver salt aqueous solution was adjusted to 60° C., and 0.00008 g of copper nitrate trihydrate (manufactured by Wako Pure Chemical Industries, Ltd.) (1 ppm in terms of copper relative to silver) was added to this silver salt aqueous solution. Addition of the copper nitrate trihydrate was performed by adding an aqueous solution obtained by diluting an aqueous solution of copper nitrate trihydrate having a relatively high concentration so as to obtain a desired amount of copper to be added.

Next, the above silver salt aqueous solution was added to the above reducing agent solution all at once, mixed, and stirred to initiate a reduction reaction. In about 10 seconds from the start of this reduction reaction, a color change of a slurry, which is a reaction liquid, was completed, and after aging for 10 minutes while stirring, the stirring was terminated. Then, solid-liquid separation was performed by suction filtration, and the obtained solid was washed with pure water, and vacuum-dried at 40° C. for 12 hours, to obtain a dry powder of silver nanoparticles (coated with hexanoic acid). The proportion of silver in the silver nanoparticles was calculated to be 97% by mass from a weight after hexanoic acid was removed by heating. Further, an average primary particle size of the silver nanoparticles was 17 nm as determined by a transmission electron microscope (TEM).

### [Metal Particles]

As the metal particles, AG-3-60 (manufactured by DOWA Hi-Tech Co., Ltd.), which are silver particles having an average primary particle size of 800 nm as measured by a scanning electron microscope, were prepared.

### [Preparation of Metal Paste for Bonding]

The metal components and non-metal components shown in Table 1 below were kneaded at a blending ratio (% by mass) shown in Table 1 to prepare bonding materials of Examples 1 to 5 and Comparative Examples 1 to 7. In Table 1, non-metal components are listed as solvents.

### [Production of Joined Body for Evaluation of Bonding Strength and Voids]

Each bonding material of Examples 1 to 5 and Comparative Examples 1 to 7 prepared above was applied to a copper substrate of 10 mm×10 mm (thickness 1 mm) with a metal mask (opening 2.5 mm×2.5 mm, thickness 70 μm). A 2 mm×2 mm (thickness 0.3 mm) Si element having a square bottom surface (surface to be bonded) was placed on a coating film of each bonding material formed on the copper substrate, and a pressure of 0.47 N was applied for 1 second. This was heated from 25° C. to 250° C. at a rate of 3° C./min in an N₂ atmosphere, and sintered at 250° C. for 60 minutes to form a silver bonding layer and obtain a joined body.

### [Evaluation of Shear Strength of the Joined Body]

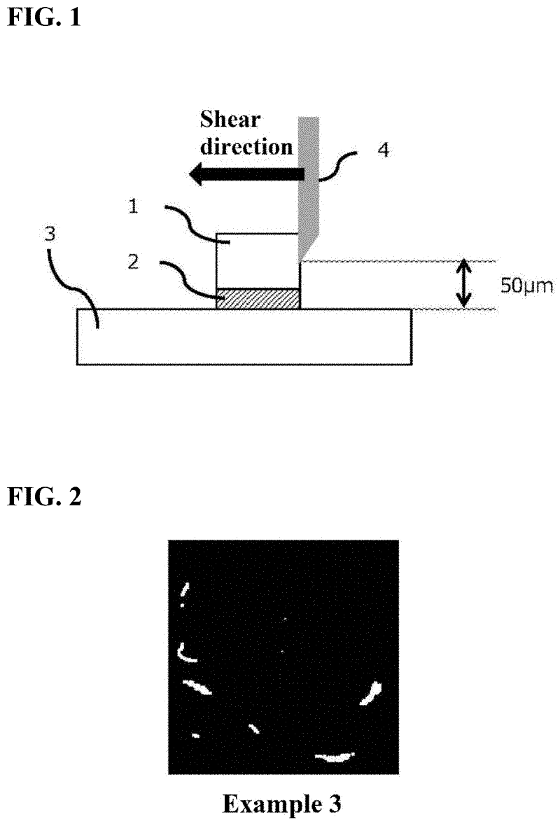

A shear strength of the joined body obtained above was measured using SERIES4000 (manufactured by DAGE) as shown in FIG. 1. Specifically, the joined body comprises a copper substrate 3, a silver bonding layer 2 formed thereon, and a Si element 1 bonded to the copper substrate 3 by the silver bonding layer 2 formed thereon. From a side surface of the Si element 1, a shear tool 4 is set at 5 mm/min and a force is applied in a horizontal direction of the copper substrate 3, and a force at break was divided by an area of a bottom surface of the Si element 1, to obtain the shear strength of the joined body. The above test was performed with a lower end of the shear tool 4 coming into contact with a position 50 μm in height from the copper substrate 3.

### [Void Evaluation]

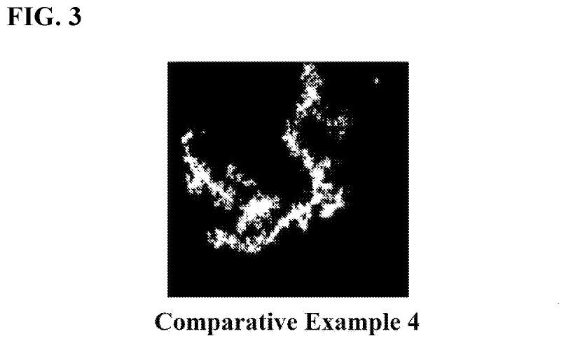

A bonding portion of the Si element—silver bonding layer—copper substrate in each joined body was photographed with a microfocus X-ray fluoroscope (SMX-16LT, manufactured by Shimadzu Corporation). A resulting image was binarized with an image processing software (trade name: Paint Shop). FIG. 2 is a result of photographing a joint formed using the metal paste for bonding in Example 3, with a microfocus X-ray transmission apparatus. FIG. 3 is a result of photographing a joint formed using a metal paste for bonding in Comparative Example 4, with a microfocus X-ray transmission apparatus. Then, a void fraction was determined. Table 1 also shows the obtained shear strength and void fraction of particles.

TABLE 1

| | | | Particle | | | | | | Com. | Com. | Com. | Com. | Com. | Com. | Com. |
|---|---|---|---|---|---|---|---|---|---|---|---|---|---|---|---|
| | | | size | Ex. 1 | Ex. 2 | Ex. 3 | Ex. 4 | Ex. 5 | Ex. 1 | Ex. 2 | Ex. 3 | Ex. 4 | Ex. 5 | Ex. 6 | Ex. 7 |
| Paste 100% | Metal | Silver nanoparticle | 17 um | 18.0 | 18.0 | 18.0 | 18.0 | 18.0 | 18.0 | 18.0 | 18.0 | 18.0 | 18.0 | 18.0 | 18.0 |
| in total | powder | Silver particle | 800 mm | 74.0 | 74.0 | 74.0 | 74.0 | 74.0 | 74.0 | 74.0 | 74.0 | 74.0 | 74.0 | 74.0 | 74.0 |
| | Solvent | Type | Boiling point | | | | | | | | | | | | |
| | | | (° C.) | | | | | | | | | | | | |

| | | | | | | | | | | | | | | |
|---|---|---|---|---|---|---|---|---|---|---|---|---|---|---|
| S_{A} | terpineol | 219 | | | | | | | | | 4.0 | | | |
| | decanol | 233 | 5.9 | 3.7 | 3.7 | 3.7 | 3.7 | 7.4 | 7.2 | 7.0 | 3.7 | 3.7 | 2.7 | 1.7 |
| | diethylene | 245 | | | | | 4.0 | | | | | | | |
| | glycol | | | | | | | | | | | | | |
| | IPTL-A | 255 | | | 4.0 | | | | | | | | | |
| | IPTL-B | 278 | | | | 4.0 | | | | | | | | |
| S_{B} | MTPH | 318 | 2.0 | 2.0 | | | | | | | | 4.0 | 5.0 | 6.0 |
| | D540 | 700 | 0.1 | 0.2 | 0.3 | 0.3 | 0.3 | 0.6 | 0.8 | 1.0 | 0. | 9.3 | 0.3 | 0.3 |

| | Total solvent (mass %) | 8.0 | 8.0 | 8.0 | 8.0 | 8.0 | 8.0 | 8.0 | 8.0 | 8.0 | 8.0 | 8.0 | 8.0 |
|---|---|---|---|---|---|---|---|---|---|---|---|---|---|
| Solvent ratio | S_{A} (%) | 5.9 | 5.8 | 7.7 | 7.7 | 7.7 | 7.4 | 7.2 | 7.0 | 7.7 | 3.7 | 2.7 | 1.7 |
| in paste | S_{B} (%) | 2.1 | 2.2 | 0.3 | 0.3 | 0.3 | 0.6 | 0.8 | 1.0 | 0.3 | 4.3 | 5.3 | 6.3 |
| | SB composition ratio in solvent (%) | 26.3 | 27.5 | 3.8 | 3.8 | 3.8 | 7.5 | 10.0 | 12.5 | 3.8 | 53.8 | 66.3 | 78.8 |
| TG heat loss | L₁₀₀ (%) | 38.3 | 32.9 | 36.8 | 28.2 | 42.3 | 35.6 | 34.4 | 31.2 | 76.5 | 22.1 | 17.5 | 15.9 |
| Percentage to L₇₀₀ | L₁₅₀ (%) | 97.8 | 97.3 | 96.9 | 94.7 | 96.8 | 93.6 | 90.9 | 87.7 | 95.9 | 86.4 | 75.9 | 75.3 |
| | L₂₀₀ (%) | 98.4 | 99.8 | 99.4 | 99.5 | 99.3 | 96.4 | 94.6 | 92.6 | 98.0 | 99.6 | 98.6 | 99.3 |

| | | | | | | | | | | | | |
|---|---|---|---|---|---|---|---|---|---|---|---|---|
| Shear strength (MPa) | 12.6 | 15.8 | 69.6 | 63.2 | 48.6 | 35.3 | 39.6 | 39.4 | 8.9 | 46.5 | 49.6 | 72.0 |
| Void fraction (%) | 0.0 | 5.0 | 1.5 | 1.1 | 0.0 | 22.0 | 17.0 | 24.4 | 8.8 | 11.3 | 16.6 | 16.8 |

### Preparation of the Metal Paste for Bonding (Example 6 and Comparative Example 8)

### (Preparation of Metal Nanoparticles)

3400 g of water was put in a 5 L reaction tank, and dissolved oxygen was removed by flowing nitrogen into the water in the reaction tank at a flow rate of 3000 mL/min for 600 seconds from a nozzle provided at a bottom of the reaction tank. Then, nitrogen was supplied into the reaction tank from a top of the reaction tank at a flow rate of 3000 mL/min to make an inside of the reaction tank a nitrogen atmosphere, and a temperature of the water in the reaction tank was adjusted to 60° C. while stirring with a stirring rod equipped with a stirring blade provided in the reaction tank. 7 g of ammonia water containing 28% by weight of ammonia was added to the water in the reaction tank, then, a mixture was stirred for 1 minute to form a uniform solution. 45.5 g of saturated fatty acid hexanoic acid (manufactured by Wako Pure Chemical Industries, Ltd.) (molar ratio to silver: 1.98) was added as an organic compound to the solution in the reaction tank and dissolved by stirring for 4 minutes. Then, 23.9 g (4.82 equivalents to silver) of 50% by weight hydrazine hydrate (manufactured by Otsuka Chemical Co., Ltd.) was added as a reducing agent to prepare a reducing agent solution.

Further, an aqueous silver nitrate solution prepared by dissolving 33.8 g of silver nitrate crystals (manufactured by Wako Pure Chemical Industries, Ltd.) in 180 g of water was prepared as an aqueous silver salt solution, and a temperature of the aqueous silver salt solution was adjusted to 60° C., and 0.00008 g of copper nitrate trihydrate (manufactured by Wako Pure Chemical Industries, Ltd.) (1 ppm in terms of copper relative to silver) was added to this silver salt aqueous solution. Addition of the copper nitrate trihydrate was performed by adding an aqueous solution obtained by diluting an aqueous solution of copper nitrate trihydrate having a relatively high concentration so as to obtain a desired amount of copper to be added.

Next, the above silver salt aqueous solution was added to the above reducing agent solution all at once, mixed, and stirred to initiate a reduction reaction. In about 10 seconds from the start of this reduction reaction, the color change of a slurry, which is a reaction liquid, was completed, and after aging for 10 minutes while stirring, the stirring was terminated. Then, solid-liquid separation was performed by suction filtration, and the obtained solid was washed with pure water and vacuum-dried at 40° C. for 12 hours, to obtain a dry powder of fine silver particles (coated with hexanoic acid). The proportion of silver in the fine silver particles was calculated to be 97% by weight from the weight after hexanoic acid was removed by heating. Further, an average primary particle size of the fine silver particles was 17 nm as determined by a transmission electron microscope (TEM).

### [Metal Particles]

As the metal particles, AG-3-60 (manufactured by DOWA Hi-Tech Co., Ltd.), which are silver particles having an average primary particle size of 800 nm as determined by a scanning electron micrograph (SEM image), were prepared. For comparison, AG-2-1C (manufactured by DOWA Hi-Tech Co., Ltd.) having an average primary particle size of 300 nm as determined by a scanning electron micrograph (SEM image) was prepared.

### [Preparation of Metal Paste for Bonding]

The bonding materials of Example 1 and Comparative Example 1 were prepared by kneading the silver particles and solvent and other components shown in Table 1 below at a blending ratio (% by mass) shown in Table 1.

### [Thermomechanical Analysis of Metal Particles]

A total of 100 g of fine silver particles and AG-3-60 were weighed at the same mass ratio (20:72=21.7:78.3) as a mixing ratio of these silver particles in Example 1 of Table 1. Further, a total of 100 g of the fine silver particles and AG-2-1C were weighed at the same mass ratio (20:72=21.7:78.3) as the mixing ratio of these silver particles in Comparative Example 1 of Table 1.

Each was weighed, then stirred with a spatula, and then stirred with a kneader/deaerator for 30 seconds. A revolving speed of a container of a kneading/defoaming machine was 1400 rpm, and a rotation speed was 700 rpm.

0.5 g of the stirred silver particles were put into a cylindrical container with an inner diameter of 5 mm and open at a top, and a load of 2000N was applied thereto for 20 seconds to form a cylindrical sample with a diameter of 5 mm and a thickness of 3.5 to 3.7 mm.

Each obtained sample was subjected to thermomechanical analysis under the following conditions.

### Manufacturer: SII (Seiko Instruments Inc.)

Model number: TMA/SS6200
Heating rate: 3° C./min
Measurement temperature: 30 to 700° C.
Measurement load: 700 mN (probe area: φ3 mm, so equivalent to 0.1 MPa)
Measurement atmosphere: Nitrogen was passed through a thermomechanical analyzer at a flow rate of 200 mL/min.

### [Preparation of the Joined Body for Evaluation]

Each bonding material of Example 1 and Comparative Example 1 prepared above was applied to a copper substrate of 30 mm×30 mm (thickness 1 mm) using a metal mask (opening 13.5 mm×13.5 mm, thickness 150 μm). A Si element having a square bottom and having a size of 13 mm×13 mm (thickness: 0.3 mm) was placed on the coating film of each bonding material formed on the copper substrate. This was heated from 25° C. to 250° C. at a rate of 3° C./min in an N₂ atmosphere, and sintered at that temperature for 60 minutes without pressure to form a silver bonding layer and obtain a joined body.

### <Void Evaluation>

The bonding portion of the Si element—silver bonding layer—copper substrate in each joined body is photographed from the Si element side using a probe (transducer) of 50 MHz with an ultrasonic microscope (C-SAMD-9500, manufactured by sonoscan). After binarizing the obtained image with image processing software (trade name: Paint Shop), an area ratio of voids was determined, between the Si element and the silver bonding layer in an area A on a surface of the Si element that contacts the silver bonding layer, where a distance from the side forming a contour is within 20% of a distance from a center of a contact surface to the side, that is an area within 1.3 mm from each side of the Si element. A black portion was judged to have no voids, and a white portion was judged to have voids.

The void rate in the area A in the case of using the bonding material of Example 6 was 8.1%, and the void rate in the area A in the case of using the bonding material of Comparative Example 1 was 45.2%.

TABLE 2

| | | | Particle | | |
|---|---|---|---|---|---|
| | | | size | Ex. 6 | Com. Ex. 8 |
| Paste 100% | Metal | Silver nanoparticle | 17 nm | 20.0 | 20.0 |
| in total | powder | Silver particle A | 300 nm | | 72.0 |
| | | (2-1C manufactured by DOWA) | | | |
| | | Silver particle B | 800 nm | 72.0 | |
| | | (3-60 mamdactured by DOWA) | | | |
| | Solvent | Type | Boiling point | | |
| | | | (° C.) | | |

| | | | | |
|---|---|---|---|---|
| S_{A} | terpineol | 219 | | |
| | decanol | 233 | 4.8 | 4.8 |
| | diethylene | 245 | | |
| | glycol | | | |
| | IPTL-A | 255 | 3.0 | 3.0 |
| | IPTL-B | 278 | | |
| S_{B} | MIPH | 318 | | |
| | D540 | 700 | 0.2 | 0.2 |

| | Total solvent (mass %) | 8.0 | 8.0 |
|---|---|---|---|
| Solvent ratio | S_{A} (%) | 7.8 | 7.8 |
| in paste | S_{B} (%) | 0.2 | 0.2 |
| | S_{B} composition ratio in solvent (%) | 2.5 | 2.5 |
| Shrinkage rate | 175° C. (%) | 0.22 | 0.30 |
| | 200° C. (%) | 0.31 | 0.55 |
| | 250° C. (%) | 0.55 | 1.87 |

| | | |
|---|---|---|
| Shear strength (MPa) | 17.4 | 12.3 |
| Void traction (%) | 8.1 | 45.2 |

1. A metal paste for bonding containing at least metal nanoparticles (A) having a number average primary particle size of 10 to 100 nm, wherein a cumulative weight loss value (L₁₀₀) when a temperature is raised from 40° C. to 100° C. is 75 or less, and a cumulative weight loss value (L₁₅₀) when a temperature is raised from 40° C. to 150° C. is 90 or more, and a cumulative weight loss value (L₂₀₀) when a temperature is raised from 40° C. to 200° C. is 98 or more, based on 100 cumulative weight loss value (L₇₀₀) when the paste is heated from 40° C. to 700° C. at a heating rate of 3° C./min in a nitrogen atmosphere.

2. The metal paste for bonding according to claim 1, wherein a cumulative weight loss value (L₂₀₀) when a temperature is raised from 40° C. to 200° C. is 99.9 or less.

3. The metal paste for bonding according to claim 1, wherein a solvent whose boiling point or decomposition temperature is Tb−50 (° C.) or more and Tb+50 (° C.) or less, accounts for 5% by mass or more and 10% by mass or less when a sintering temperature is Tb (° C.), based on 100% by mass total amount of the metal paste for bonding containing metal particles containing metal nanoparticles (A), solvents, and additives such as a dispersant.

4. The metal paste for bonding according to claim 1, the metal paste containing 1.5% by mass or less of a component whose boiling point or decomposition temperature is higher than the sintering temperature Tb+50 (° C.) when the sintering temperature is Tb (° C.), based on 100% by mass total amount of the metal paste for bonding containing metal particles containing metal nanoparticles (A), solvents, and additives such as a dispersant.

5. A metal paste for bonding, which is a metal paste for bonding containing metal particles containing metal nanoparticles (A) having a number average primary particle size of 10 to 100 nm, wherein a shrinkage rate of the metal particles contained in the paste is 1.5% or less, the shrinkage rate being measured by thermomechanical analysis performed while pressurizing the metal particles at 0.1 MPa in a nitrogen atmosphere and raising a temperature from 30° C. to 250° C. at a rate of 3° C./min.

6. The metal paste for bonding according to claim 5, wherein a shrinkage rate of the metal particles is 0.5% or less, the shrinkage rate being measured in thermomechanical analysis performed while raising a temperature from 30° C. to 200° C.

7. The metal paste for bonding according to claim 5, wherein a shrinkage rate of the metal particles is 0.3% or less, the shrinkage rate being measured in thermomechanical analysis performed while raising a temperature from 30° C. to 175° C.

8. A metal paste for bonding according to claim 1, the metal paste further containing metal particles (B) whose average particle size (D₅₀) is 1.0 to 5.0 μm in terms of volume measured by a laser diffraction particle size distribution device.

9. The metal paste for bonding according to claim 8, wherein a weight mixing ratio of metal nanoparticles (A) to metal particles (B), (A)/(B), is 0.25 or less.

10. A bonding method which is a method for bonding two members to be bonded, the method comprising:
applying the metal paste for bonding according to claim 1, to a member to be bonded;
placing one member to be bonded on which the paste is applied on a coating film, on the other member to be bonded; and
raising a temperature to a sintering temperature of 200 to 350° C. after placing the members, and maintaining the sintering temperature for less than 2 hours to form a metal bonding layer.

11. The bonding method according to claim 10, comprising drying at a temperature of 50 to 150° C. after applying the metal paste for bonding.

12. The bonding method according to claim 10, wherein a temperature rise rate from a room temperature to a sintering temperature is 1.5 to 10° C. per minute.

13. The bonding method according to claim 10, wherein an area (bonding area) to which the metal paste for bonding is applied is 9 mm² or more.
